(19) United States
(12) Patent Application Publication
(10) Pub. No.: US 2021/0048910 A1
(43) Pub. Date: Feb. 18, 2021

(54) MODULAR TOUCH PANEL SMART SWITCHES AND SYSTEMS

(71) Applicant: HOGAR CONTROLS, INC., Sterling, VA (US)

(72) Inventors: Karun Kumar ANADASU, Hyderabad (IN); Ashwanth Kumar ANADASU, Hyderabad (IN)

(73) Assignee: HOGAR CONTROLS, INC., Sterling, VA (US)

(21) Appl. No.: 17/085,393

(22) Filed: Oct. 30, 2020

Related U.S. Application Data
(63) Continuation of application No. 16/268,997, filed on Feb. 6, 2019, now abandoned.

(51) Int. Cl. G06F 3/041; G06F 9/30; G06F 1/16; H03K 17/96

(52) U.S. Cl. CPC G06F 3/0412; G06F 3/0416; H03K 17/96; G06F 1/1643; G06F 9/30043

(57) ABSTRACT

A touch panel smart switch includes a switch module comprising and a removable faceplate module communicatively couple to the switch module. The faceplate module includes a touch sensor, a display device, a processor, and a memory. The touch sensor is configured to detect a touch input by a user, and the display device is configured for displaying virtual switches at locations at which the touch sensor can detect a touch input by the user. The processor displays a first virtual switch at a first location on the display device, and selectively connects a first load to a power source using the switch module in response to the touch sensor detecting a touch input by the user at the first location of the first virtual switch displayed on the display device.

The present application is a continuation of U.S. application Ser. No. 16/268,997, filed Feb. 6, 2019. The disclosure of the above-identified prior application is hereby incorporated by reference.

### BACKGROUND

This disclosure relates generally to the field of electrical switches, and more specifically to modular, touch panel smart switches and systems.

Traditional light switches include a toggle, button, slider, or the like that can be actuated by a user to selectively connect or disconnect a load, such as a light, an outlet, a fan, or the like, from an electrical power source. Such traditional light switches generally only control loads wired to the particular switch and require a user to physically actuate the switch.

Smart switches, also sometimes referred to as intelligent switches, connected switches, or smart home switches, generally include communications capabilities. The communications capabilities variously allow the smart switch to be remotely controlled by a user or a computing device, and allow the smart switch to communicate with a user (such as via an application on a smartphone), with other smart switches, and/or with other smart devices. At least some known smart switches have a form factor similar to traditional light switches. That is, they include a toggle, one or more buttons, a slider, or the like. Such smart switches generally have a configuration that provides a predetermined and fixed interface for the user, and control options may be limited based on the predetermined configuration.

At least some known smart switches include a touch panel interface, rather than a physical button, toggle, slider, or the like. With at least some such touch panel smart switches, different complete assemblies are needed depending on the size of the electrical box. That is, a first smart switch is needed for a 1-gang electrical box, a different second smart switch is needed for a 2-gang electrical box, a third smart switch that is different from the first and second smart switches is needed for a 3-gang electrical box, and so on. Additionally, in at least some of the known touch panel smart switches, two 1-gang configuration smart switches will not fit in a 2-gang electrical box.

### SUMMARY

One aspect of the present disclosure is a touch panel smart switch including a switch module and a removable faceplate module. The switch module includes a first terminal for connection to a first load, a second terminal for connection to a power source, and a first relay connected to the first terminal and the second terminal for selectively connecting and disconnecting the first load to the power source. The removable faceplate module is communicatively couple to the switch module. The faceplate module includes a touch sensor configured to detect a touch input by a user, a display device configured for displaying virtual switches at locations at which the touch sensor can detect a touch input by the user, a processor communicatively coupled to the touch sensor, the display device, and the switch module, and a memory device storing instructions. When executed by the processor, the instructions cause the processor to display a first virtual switch at a first location on the display device, and selectively connect the first load to the power source using the first relay in response to the touch sensor detecting a touch input by the user at the first location of the first virtual switch displayed on the display device.

According to another aspect of the disclosure, a method of installing touch panel smart switches includes installing N switch modules in an N-gang electrical box, and selecting a faceplate module for N switch modules from a plurality faceplate modules. N is an integer value greater than 0, and each switch module includes at least one relay for selectively connecting and disconnecting at least one load to a power source. Each faceplate module of the plurality of faceplate modules is configured for of use with a different number of switch modules. The selected removable faceplate module includes N touch assemblies and N control board assemblies. Each touch assembly includes a touch sensor configured to detect a touch input by a user. Each control board assembly includes a display device and a control board. The control board includes a processor and a memory device storing instructions for execution by the processor. The method further includes communicatively coupling each of the N control board assemblies to a different one of the N switch modules.

### BRIEF DESCRIPTION OF THE DRAWINGS

The disclosure will be described with reference to the accompanying drawings, wherein like numbers reference like elements.

FIG. 1 is a diagram illustrating an example system including smart switches according to embodiments of this disclosure.

FIG. 2 is a block diagram of an example smart switch according to this disclosure.

FIG. 3 is an exploded view of an example embodiment of smart switch and a 1-gang electrical box.

FIG. 4 is a partially exploded view of the smart switch shown in FIG. 3.

FIG. 5 is a partially exploded view of an installation of two smart switches in a 2-gang electrical box, with a 2-gang frame and a 2-gang bezel.

FIG. 6 a partially exploded view of an installation of three smart switches in a 3-gang electrical box, with a 3-gang frame and a 3-gang bezel.

FIG. 7 a partially exploded view of an installation of four smart switches in a 4-gang electrical box, with a 4-gang frame and a 4-gang bezel.

FIG. 8 is an enlarged partial front view of multiple insulating cases installed in the electrical box shown in FIG. 7.

FIG. 9 is a front view of the example smart switch shown in FIGS. 3 and 4 in a sleep mode.

FIG. 10 is a front view of the example smart switch shown in FIG. 9 in an awake mode.

### DETAILED DESCRIPTION OF EMBODIMENTS

This disclosure relates generally to the field of electrical switches, and more specifically to modular, touch panel smart switches and systems.

Various embodiments of the present disclosure are directed to smart switches using touch panel interfaces, rather than physical buttons, toggles, or sliders. Moreover, the smart switches are modular, allowing them to be used in electrical boxes of different sizes (e.g., 1-gang, 2-gang, 3-gang, etc.). Additionally, in some embodiments, each smart switch may be physically connected to, such as by appropriate wiring, more than one load, which the smart switch may control. Further, each smart switch may remotely control one or more additional loads to which it is not physically connected. The number of virtual switches, which are virtual equivalents to the mechanical toggles, buttons, etc. in a traditional, non-smart switch, and the particular representation of each virtual switch may be varied depending on the number of loads physically connected to the smart switch, the number of loads remotely controlled (but not physically connected to the smart switch), and the user's preferences. The above-described features and other features will be described in further detail below.

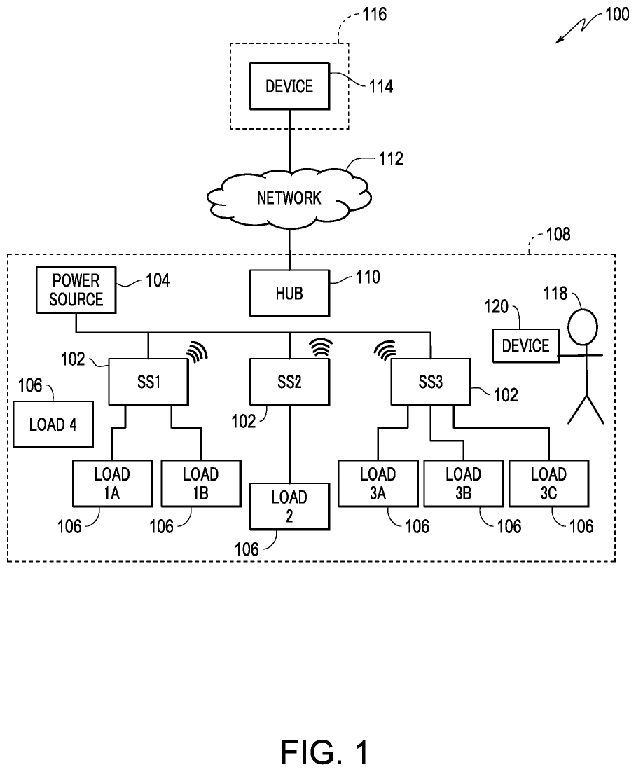

FIG. 1 is a block diagram illustrating an example system 100 including smart switches 102 according to embodiments of this disclosure. Each of the smart switches 102 is connected between a power source 104 and at least one load 106 within a location 108. Specific smart switches 102 in FIG. 1 may be identified as smart switch SS1, smart switch SS2, or smart switch SS3, as appropriate. Similarly, particular loads 106 in FIG. 1 may be identified as load 1A, load 1b, load 2, load 3A, etc. The location 108 may be a house, an apartment, an office building, or any other suitable location for installation of electrical switches. The power source 104 provides electrical power for powering loads 106 at the location 108. The loads 106 may be any loads suitable for control using a smart switch, such as a light, an electrical outlet, a fan, or the like. In addition to controlling the load(s) 106 physically connected to it, each switch may control one or more other loads 106 that are not physically connected to that particular smart switch 102.

The smart switches 102 communicate with a hub 110. The communication between the smart switches 102 and the hub 110 is wireless communication using any suitable communications protocol. In some embodiments, each of the smart switches 102 communicates directly with the hub 110. In other embodiments, the smart switches 102 form a mesh network and at least some of the switches 110 communicate to the hub through other of the smart switches 102. In still other embodiments, the hub 110 is not included.

The smart switches 102 are also operable to communicate with each other. The communication between smart switches 102 may be conducted through the hub 110 or by direct communication between switches without using the hub 110. By communicating with other smart switches 102, a smart switch 102 may instruct the other switch to switch on/off one of its loads, to thereby remotely control a load 106 to which it is not physically connected. Thus, for example, smart switch SS1 may include a virtual switch that causes smart switch SS1 to instruct smart switch SS2 to turn on/off load 2. Some loads 106, for example load 4 may be directly controlled by a smart switch 102 to which they are not physically connected, such as a smart light bulb, which may be considered as a light bulb with its own smart switch built in.

In an example embodiment, the smart switches 102 communicate using Wi-Fi communication. In some embodiments, the smart switches 102 communicate using the Z-Wave® protocol. In other embodiments, the smart switches 102 communicate using any other suitable wired and/or wireless communication, including ZigBee, Insteon, X10, Bluetooth® or the like. In some embodiments, smart switches 102 communicate using more than one communications protocol.

In some embodiments, the hub 110 is connected to a network 112, such as the Internet. In other embodiments, the hub 110 is connected to a local area network or not connected to any network. The connection between the hub 110 and the network 112 may be a wireless connection or a wired connection using any suitable communications protocol. By connecting to a network, particularly when the network 112 is the Internet, the ability to control the smart switches 102 may be extended beyond the location 108. Thus, a device 114 located outside of the location 108 in a remote location 116 may communicate with the hub 110 to learn the status of the smart switches 102 (e.g., whether they are on or off) and to control the smart switches 102 from the remote location 116. The device 114 may be any suitable network connected device capable of communication with the hub 110, such as a personal computer, a mobile phone, a tablet computer, a smart watch, or the like.

A user 118 located at the location 108 may also control the smart switches 102. Obviously, such a user 118 can control the switches by physical interaction with the smart switches 102 at the location. Additionally, the user may control the smart switches 102 and determine the status of the smart switches 102 using a user device 120. The user device 120 may be a personal computer, a mobile phone, a tablet computer, a smart watch, or the like. The user device may interact with the smart switches 102 by communicating to the hub directly or through the network 112, or may communicate directly with the switches without using the hub. Moreover, in some embodiments, the user 118 may interact with the smart switches 102 using voice commands. That is, in such embodiments, the smart switches 102 include a microphone to detect voice commands announced by the user 118 and are programmed to act upon the appropriate voice commands.

In some embodiments, the smart switches 102 include one or more sensors (not shown in FIG. 1). The sensors may include temperature, proximity, motion, light sensor, or any other suitable sensor. A temperature sensor allows the smart switch 102 to provide a room temperature display on a display panel (not shown in FIG. 1) of the smart switch 102 and to send temperature information to connected hub 110. The temperature information sent to the hub may be used, for example, as part of a control scheme for an HVAC system and/or to send temperature alerts a remotely located device, such as device 114 or device 120. A proximity sensor detects movement, such as hand movement, near the smart switch 102, which may be used to awaken or brighten a display on the smart switch 102. A motion sensor detects human motion at a longer range than the proximity sensor and sends information to the hub 110. In some embodiments, the motion sensor detects human motion within a range of about ten meters. The motion detection may be used for similar purposes, or in conjunction with, the proximity detection, may be used for security purposes, may be used to control lights based on human motion within the location 108, or for any other suitable purposes. A light sensor senses the lux level around near the switch and sends such information to the hub 110. This information may be used for adjusting the brightness of a display on the smart switch, adjusting the light level in the location 108, or for any other suitable purposes.

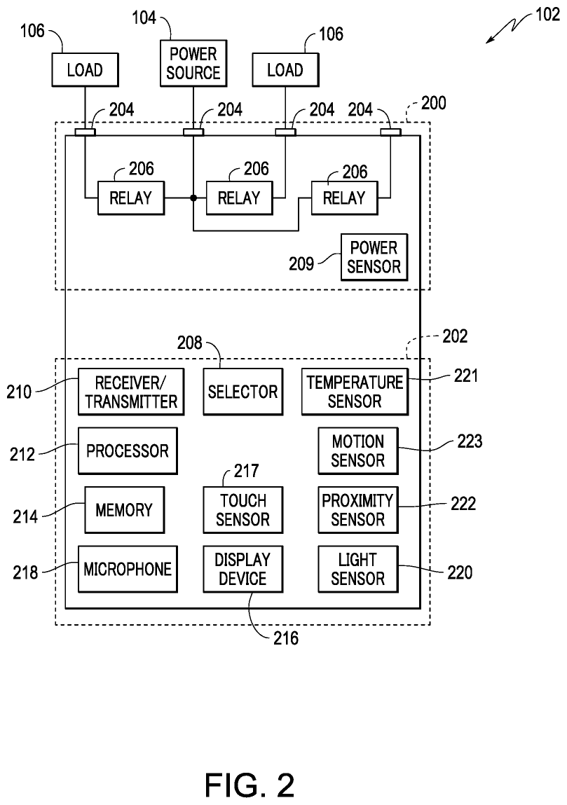

FIG. 2 is a block diagram of an example smart switch 102 according to the present disclosure. The smart switch 102 includes two main components: a switch module 200 and a faceplate module 202. In the example embodiment, the switch module 200 handles the switch of the electrical connection to the loads 106 and the faceplate module 202 provides the virtual switches, the communications, and the customization. The faceplate module 202 also commands the switch module 200. The faceplate module 202 is removably coupled to the switch module 200, allowing the faceplate module 202 to be mechanically and electrically removed and replaced with a different faceplate module (e.g., one sized for a different size electrical box, configured for use with more than one switch module 200, and/or having a different appearance or different features), while using the same switch module 200.

The switch module 200 includes terminals 204 for connection to the power source 104 and the loads 106. The terminals 204 for connection to loads 106 are sometimes referred to as output terminals, while the terminal(s) 204 connected to the power source 104 are sometimes referred to as input terminals. A relay 206 is connected between the power source 104 and each load 106. The relays 206 are the switches that open or close the connection of the load 106 to the power source 104. Although the example embodiment includes three relays 206 in the switch module 200, other embodiments may include more or fewer relays 206. Some embodiments, for example, include four relays 206. In the example embodiment, each relay 206 is a 110-220 volt AC relay rated for 10 amps of current. In other embodiments, on or more of the relays 206 is a semiconductor relay that variably controls the output voltage between 0 volts and the input voltage (e.g., 110 VAC or 220 VAC), to allow dimming of light(s) connected to the relay 206.

In the example embodiment, how many and which of the relays 206 are to be used in the switch module 200 is customizable and selectable through a selector 208 in the faceplate module 202. The selector 208 is a software module accessed by the user 118 (such as through use of an application on device 120 or through a display on the faceplate module 202) to instruct the smart switch 102 which relays 206 are to be used. In other embodiments, the selection of how many and which of the relays 206 are to be used in the switch module 200 is performed using a selector 208, such as a mechanical or electromechanical selector, in the switch module 200 (not shown in the switch module in FIG. 2). In FIG. 2, only two relays 206 are connected to loads 106. Thus, use of the particular two relays 206 connected to loads 206 would be selected. In other installations, different numbers of the available relays 206 may be used, and the faceplate module 202 or the selector 208 would be used to select which relays 206 should be used. In some embodiments, the selector 208 is a three position dip switch. By setting each position of the dip switch to on or off, the user tells the smart switch 102 which of the relays 206 to use. In FIG. 2, for example, the first and second positions of the dip switch would be set to on and the third position would be set to off, to inform the smart switch 102 that the first and second relays 206 (from left to right in FIG. 1) are to be used. In other embodiments, other types of selectors 208 may be used, such as a rotary switch, individual switches at each terminal 204, etc. In still other embodiments, the selector may be an automatic selector that detects which relays 206 are connected to one of the loads 106. Such an automatic selector may be implemented in hardware, software, or a combination of hardware and software.

The switch module includes a power monitor 209. The power monitor 209 monitors the power consumed by the load(s) connected to the smart switch 102 and transmits power consumption data to the hub 110. In the example embodiment, the power monitor 209 includes a current sensor (not shown) that measures the current provided to each load 106 and the smart switch 102 transmits the measured current data to the hub 110. In some embodiments, the power monitor 209 calculates the power consumption based at least in part on the measured current, and the smart switch transmits the determined power consumption to the hub 110. In some embodiments, the power monitor 209 includes one or more other sensors, such as a voltage sensor, to enable it to monitor the power consumption of the loads 106 to which the smart switch 102 is connected.

The switch module 200 is communicatively coupled to the faceplate module 202 by a communications cable (not shown in FIG. 2). The faceplate module includes a communications module 210, a processor 212 and a memory device 214, a display device 216, a touch sensor 217, a microphone 218, a light sensor 220, a temperature sensor 221, a proximity sensor 222, and a motion sensor 223. Other embodiments may include more or fewer sensors.

A communications module 210 (also sometimes referred to as a transmitter/receiver or TX/RX) transmits and receives communication from/to the smart switch 102 according to the particular communications protocol used by the smart switch 102 (e.g., WiFi, Z-Wave, etc.). In some embodiments, the communications module 110 includes a power line communications module for transmitting and receiving communications over the electrical wiring to which the smart switch 102 is connected or the communications module 110 may communicate over a separate communications wire(s) using any appropriate wired communications protocol.

The processor 212 is communicatively coupled to the communications module 210, the selector 208, the memory device 214, and the switch module 200. The processor 212 is programmed to control operation of the smart switch 102. The processor 212 is programmed by encoding an operation using one or more executable instructions and providing the executable instructions in memory device 214.

The term “processor” refers herein generally to any programmable system including systems and microcontrollers, reduced instruction set circuits (RISC), application specific integrated circuits (ASIC), programmable logic circuits (PLC), and any other circuit or processor capable of executing the functions described herein. The above examples are exemplary only, and thus are not intended to limit in any way the definition and/or meaning of the term “processor.”

The memory device 214 includes one or more devices that enable information, such as executable instructions and/or other data, to be stored and retrieved. The instructions, when executed by the processor 212, cause the processor 212 to function as described herein and to function as the software implemented modules, such as the selector 208, discussed herein. Moreover, the memory device 214 includes one or more computer readable media, such as, without limitation, random access memory (RAM), dynamic random access memory (DRAM), static random access memory (SRAM), a solid state disk, and/or a hard disk. In the example embodiment, memory device 214 stores, without limitation, application source code, application object code, configuration data, additional input events, application states, assertion statements, validation results, and/or any other type of data.

The display device 216 is a flat panel display device. In the example embodiment, the display device 216 is a passive matrix light emitting diode (PMOLED) display. In other embodiments, the display device 216 a liquid crystal display (LCD), a light emitting diode (LED) display, an organic LED (OLED) display, an “electronic ink” display, or any other suitable display device.

The touch sensor 217 is a one glass solution (OGS) capacitive touch sensor for receiving a user selection. In the example embodiment, the touch sensor 217 includes three touch points, each of which corresponds to one of the relays 206. When the user 118 touches one of the touch points, the processor 212 detects the touch and informs the switch module 200 which relay 206 to open/close. In other embodiments, any other suitable touch sensor may be used, and the touch sensor may include more or fewer touch points. In some embodiments, the user 118 may select which touch point corresponds to which relay 206. This allows the user 118 to customize the smart switch 102 for a preferred ordering of the switches regardless of to which relay 206 each load 106 is connected and without needing to move the loads to different terminals 204 to achieve different ordering. Thus, rather than needing to ensure that a certain light is connected to the first relay 206 in order for that certain light to be associated with the first touch point on the faceplate module 202, the user can simply associate the first touch point with whichever relay the certain light is wired to.

The display device 216 and the touch sensor 217 cooperatively function as a user interface for outputting information to the user 118 and for receiving a user input (i.e., a user selection of a load to turn on or off).

The processor 212 controls the display device 216 to display virtual switches (also referred to as icons) on the display device at the locations of the touch points. FIG. 10 is a front view of the example smart switch 102 connected to three loads 106 and showing three icons 900 on the display device 216. The processor 212 displays an icon at each touch point that corresponds to a relay that has been selected (using the selector 208) to be used. Thus, in the example embodiment, there are no unused switches on the smart switch 102, because virtual switches are displayed on the display device 216 only for the relays 206 that are being used. If two relays 206 are selected using the selector 208, for example, the processor 212 will not display an icon for the unused relay and will display only two icons on the display device 216 (unless the user 118 selects to display a third switch associated with a load 106 that is not physically connected to the smart switch 102).

The particular icons to be displayed at each touch point may be selected by the user 118 and will typically represent the identity of the load. For example, if the light is connected to the relay 206 associated with a touch point, the icon displayed at that touch point may be a light bulb. Similarly if the load is a fan, a fan blade may be selected to be displayed at the appropriate touch point. Alternatively, the icons may be a text icon containing the name of the load, for example “Light”, “Lamp”, or “Fan Light.” Of course, because the selection of icons is at the discretion of the user 118, the user may assign a light bulb shaped icon to represent a relay 206 connected to a fan if she so desires. The various available icons are stored in the memory 214.

The processor 212 also controls a status indicator (902 in FIGS. 9 and 10) for each relay 206 of the smart switch to indicate whether the relay is open or closed (i.e., whether the load is switched off or on). The status indicator 902 may be displayed on the display device 216 or may be separate indicators, such as light emitting diodes (LEDs). As will be discussed below, the example smart switch 102 has at least one sleep mode in which the icons are not displayed on the display device 216 (e.g., as shown in FIG. 9) or the brightness of the display device is dimmed. While in a sleep mode, the status indicators 902 continue to indicate the status of each relay 206.

The processor 212 selectively connects the loads 106 to the power source 104 using the relays 206. That is, the processor 212 connects or disconnects the loads 106 from the power source by controlling or instructing the switch module 200 to control the relays 206. The selectivity in selectively connecting the loads 106 to the power source 104 refers to multiple types of selectivity. If the relay 206 is a toggle relay (i.e., toggles between on and off), the processor connects or disconnect the load 106 from the power source 104 using the relay 206 depending on whether the relay 206 is currently off (load disconnected) or on (load connected). Additionally, the selectivity includes connecting/disconnecting the load 206 to the power source 104 in response to receiving an instruction. That is, switching the connection in response to the touch sensor 217 detecting a user input at the location of the virtual switch corresponding to a particular relay 206, or in response to an instruction received from the hub 110 or another smart switch 102 to connect/disconnect the load 206 from the power source 104. A further aspect of selectivity is the selection of which relay 106 of the multiple relays 206 in the switch module 200 is to be switched. Yet another aspect of selectivity is a selection of a degree of connection/disconnection between the load 106 and the power source 104. For example, if the relay 206 to be controlled is a dimming relay, the connection is varied (i.e., selected) according to the instruction received (e.g., fully on, fully off, 50% level, 25% level, etc.). Similarly, the time of connection may be selected (e.g., to control a load to operate for a certain length of time rather than until an instruction to cease operating is received).

The microphone 218 captures sound produced in the vicinity of the smart switch 102 and provides the captured sound to the processor 212. The processor 212 analyzes the captured sound and detects voice commands announced by the user 118 when they are captured by the microphone 218. The detected commands are sent to the hub 110, which causes the action commanded by the voice command to be taken. For example, in response to the user 118 uttering a voice command to “turn on ceiling fan,” the hub 110 will instruct the smart switch 102 to which the ceiling fan is connected to cause its switch module 200 to close its relay 206 connected to the ceiling fan. Alternatively, processing of the voice commands may be done by the processor 212 and the processor may take the predetermined action associated with the voice command directly (i.e., without involving the hub). In such embodiments, if the voice command relates to a load that is not connected to the smart switch 102 that received the voice command or otherwise does not relate to the smart switch 102, the voice command is forwarded to the hub 110 for handling by the hub. Alternatively, the smart switch 102 receiving the voice command may forward the captured sound to the hub 110 without detecting the voice commands, and the hub 110 handles detection of the voice commands and causing the corresponding action to be taken.

The light sensor 220 detects the level of light in the vicinity of the smart switch 102. In the example embodiment, the processor 212 uses the detected light level to control the brightness of the display device 216 to an appropriate level for the ambient light in the room around the smart switch 102. For example, when the room is dark around the smart switch (as sensed by the light sensor), the processor 212 reduces the brightness of the display device 216. Conversely, when the room is brightly lit, the processor 212 reduces the brightness of the display device 216. In some embodiments, the light level detected by the light sensor 220 is sent to the hub 110, which may use the light level for suitable control and/or information purposes. For example, the hub 110 may include programming to turn on a particular load connected to the smart switch 102 when the detected light level is below a certain threshold level (e.g., to turn on a light at dusk. Alternatively, the smart switch 102 itself may perform such control based on the detected light level.

The proximity sensor 222 detects the presence of the user 118 (or other person or object) near the smart switch 102. In the example embodiment the proximity sensor 222 detects the presence of the user 118 within about 20 cm of the display device 216. In other embodiments, the proximity sensor 222 may detect the user presence at a shorter or longer distance. The processor uses the detected proximity of the user 118 to vary the brightness of the display device 216 and the display of the icons on the display device. As shown in FIG. 9, when no object is detected near the smart switch 102 for a predetermined period of time, the processor 212 dims the brightness of the display device 216 and does not display the icons on the display device 216, thus placing the smart switch in a sleep mode that may reduce energy consumption and limit potentially distracting light output from the smart switch 102 (and specifically from the display device 216). In the example embodiment, the predetermined period of time is 30 seconds. In other embodiments, the predetermined time may be any other suitable length of time. In still other embodiments, the predetermined period of time may be set or selected by a user. When the proximity sensor 222 again detects an object near the smart switch, the processor 212 increases the brightness of the display device 216 and again displays the icons on the display device 216, thus allowing the user 218 to interact with the smart switch 102 as shown in FIG. 10.

In some embodiments, one or more components of the faceplate module are mounted on a common substrate or circuit board (not shown in FIG. 2). For example, the communications module 210, processor 212, memory device 214, microphone 218, light sensor 220, and proximity sensor 222 are all mounted to a common circuit board. In other embodiments, different combinations and numbers of components (including zero components) are mounted on a common circuit board.

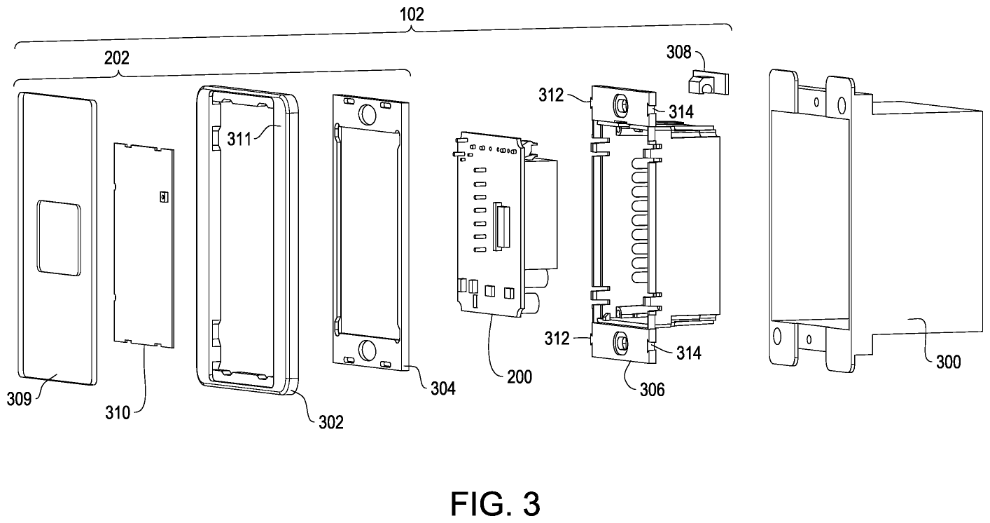

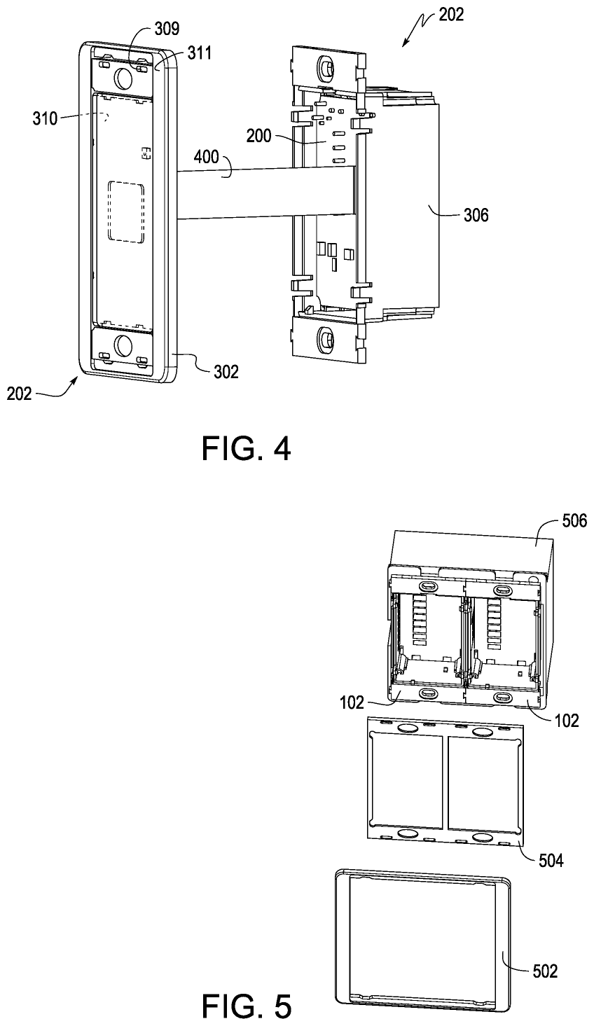

FIG. 3 is an exploded view of an example embodiment of smart switch 102 and a 1-gang electrical box 300. FIG. 4 is a partially exploded view of the smart switch 102 in FIG. 3.

With reference to FIG. 3, in this embodiment, the smart switch 102 includes the faceplate module 202, the switch module 200, a bezel 302, a frame 304, an insulating case 306, and a fuse holder 308.

The faceplate module 202 includes a touch assembly 309, a control board assembly 310, the bezel 302, and the frame 304. The touch assembly 309 includes tempered glass (not shown separately) glued to the touch sensor 217. The control board assembly 310 includes the display device 216 and a control board (neither separately labeled). The control board is a circuit board with the communications module 210, processor 212, memory device 214, microphone 218, light sensor 220, and proximity sensor 222 mounted thereon. The bezel 302 and the frame 304 cooperatively hold the touch assembly 309 and the control board assembly 310 to form the faceplate module. The bezel 302, the frame 304, and the touch assembly 309 are permanently glued together with a suitable adhesive. In other embodiments, any other assembly techniques may be used. When the smart switch 102 is installed within the electrical box 300, the bezel 302 extends beyond the outer edges of the electrical box 300 to conceal the electrical box 300. After assembly, an outer surface 311 of the bezel 302 is substantially flush with the outer surface of the touch assembly 309 to provide a smooth, flat surface of the smart switch 102. As shown in FIG. 4, the faceplate module 202 (and specifically, the control board assembly 310, is connected to the switch module 200 by a connector 400. In the example embodiment, the connector 400 is a 12 pin, thin, plug-n-play, flat pin connector. Other embodiments may use any other suitable type of connector for connector 400.

The two part construction of the smart switch 102 using a faceplate module 202 and a switch module 200 allows the use of different types of switch modules 200 with the same faceplate module. For example, switch modules 200 specifically configured for on/off switching, dimming, fan control, curtain control, and the like may each be used with the same faceplate module 202. This may permit flexibility of installation and/or upgrading while maintaining a uniform appearance of all types of switches, and reduces the number of different types of components that need to produced, stocked, maintained, inventoried, etc.

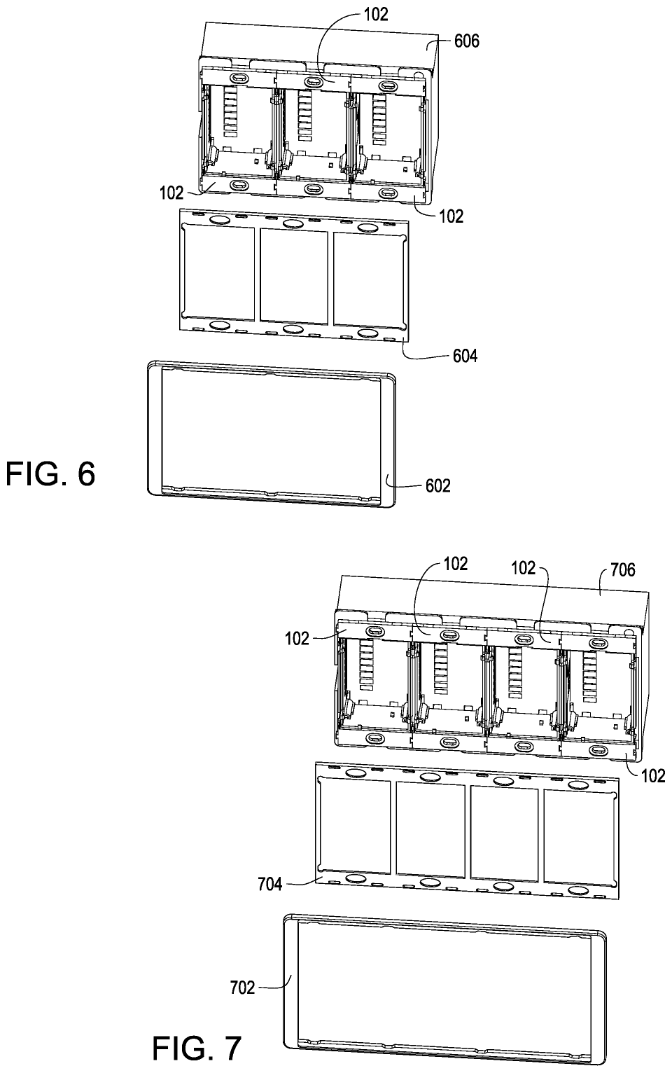

The insulating case 306 is constructed of an electrically insulating material, such as a plastic, and is sized to fit within the electrical box 300. As shown in FIG. 4, the insulating case 306 holds the switch module 200 and provides electrical insulation between the switch module 200 and the electrical box 300. Moreover, the insulating case 306 is sized small enough that a same number of insulating cases 306 can fit in an electrical box as the gang size of the electrical box. That is, the insulating case 306 is sized such that one insulating case 306 will fit within a 1-gang box, two insulating cases 306 will fit side by side within a 2-gang electrical box 506 (as shown in FIG. 5), three insulating cases 306 will fit side by side within a 3-gang electrical box 606 (as shown in FIG. 6), four insulating cases 306 will fit side by side within a 4-gang electrical box 706 (as shown in FIG. 7), etc.

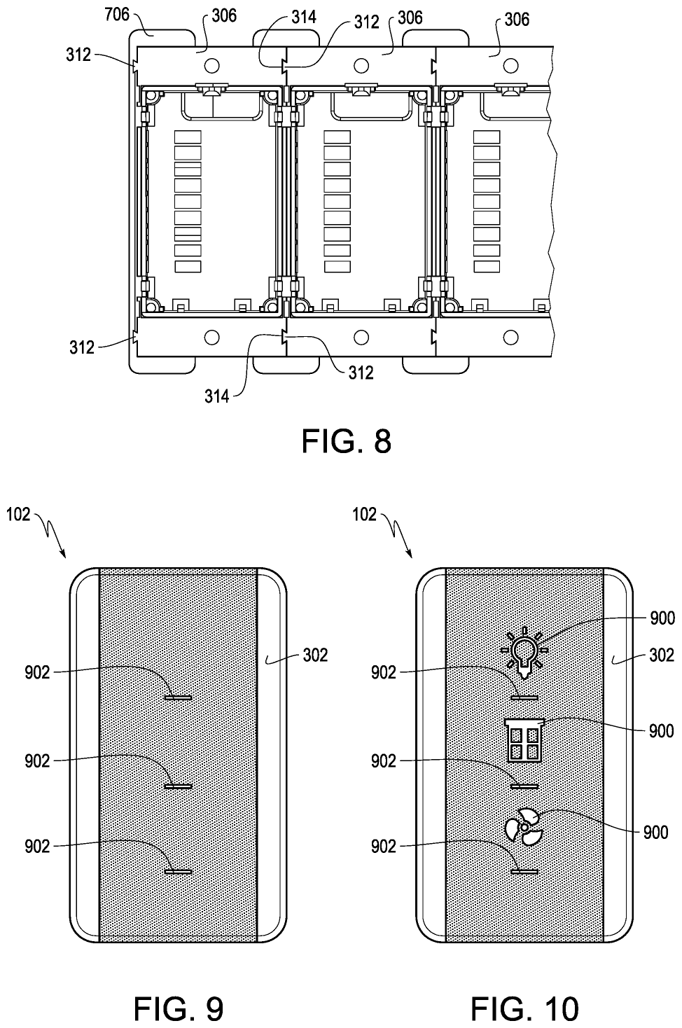

Additionally, the insulating case 306 includes interlocking connectors 312 and 314 (also seen in FIG. 8) on its sides. The interlocking connecters 312 are male connectors, and the interlocking connectors 314 are female connectors corresponding to the interlocking connectors 312. In the example embodiment, two interlocking connecters 312 are located on one side of the insulating case 306, and two interlocking connecters 314 are located on the opposing side of the insulating case 306. In other embodiments, more or fewer of each type of interlocking connecters 312, 314 may be used and/or the same type of interlocking connecter 312, 314 need not all be located on the same side of the insulating case 306 (so long as each interlocking connecter 312, 314 on one side of the insulating case 306 has the other interlocking connecter 314, 312 on the opposing side of the insulating case 306). As can be seen in FIG. 8, when multiple insulating cases 306 are installed side by side in a multiple-gang electrical box, the interlocking connecters 312, 314 of one insulating case 306 connect to the interlocking connecters 314, 312 of the adjacent insulating case 306 to align and connect the adjacent insulating cases 306 together.

The combination of the features of the insulating case 306 and the frame 304 and bezel 309 combine to provide at least some of the modular aspects of the present disclosure. As explained above, multiple insulating cases 306 may be installed within a multiple-gang box. The switch module 200 fits entirely within the insulating case 306, which fits within the gang box in which the smart switch is being installed. The faceplate module 202 shown in FIGS. 3 and 4, however, is deliberately larger than the outside of the 1-gang electrical box (in order to completely cover the electrical box). Because of the sizing of a multiple gang boxes, multiple known 1-gang touch-panel smart switches cannot fit within a multiple-gang electrical box, because multiple-gang boxes do not increase in width at the same rate as the number of switches they are designed to hold. That is, a 2-gang box is less than two times as wide as a 1-gang box, and a 3-gang box is less than three times as wide as a 1-gang-box. For example, a known 1-gang box has an interior width of about 52.8 mm, a known 2-gang box has a width of 96.8 mm, a known 3-gang box has a width of 146.9 mm, and a known 4-gang box has a width of 192 mm. The example insulating case 306 has a width of 45.8 mm, and thus two can fit in a 2-gang box, three can fit in a 3-gang box, four can fit in a 4-gang box, etc. In other embodiments, the width of the insulating case is any other suitable width less than about 48 mm. In other example embodiments, the width of the insulating case 306 is about 47 mm, about 46 mm, and about 45 mm. The maximum width of the insulating case 306 may also be defined relative to the width of a multiple-gang electrical box. Thus for example, the insulating case 306 may have a width of less than one-fourth the width of a 4-gang electrical box, thus allowing four insulating cases 306 (and therefore four smart switches 102) to be installed in a 4-gang electrical box.

The modular smart switches according to the present disclosure are able to fit multiple switches within a multiple-gang box because of the sizing of the insulating case 306, and the sizing of the separate and interchangeable faceplate module 202 (and particularly the sizing of the bezel 302). As shown in FIGS. 5-7, different sized bezels and frames are used (with the rest of the components of the smart switch 102 remaining the same) to allow multiple smart switches 102 to fit into multiple-gang electrical boxes 300. FIG. 5 shows an installation of two smart switches 102 in a 2-gang electrical box 506, with a 2-gang frame 504 and a 2-gang bezel 502. FIG. 6 shows an installation of three smart switches 102 in a 3-gang electrical box 606, with a 3-gang frame 604 and a 3-gang bezel 602. FIG. 7 shows an installation of four smart switches 102 in a 4-gang electrical box 706, with a 4-gang frame 704 and a 4-gang bezel 702.

Thus, the various embodiments described above provide a modular system of touch panel smart switches. The modular nature permits the example smart switches to be used in multiple different installations using the same or mostly the same components. Completely different switch assemblies do not need to be purchased in order to install the touch panel smart switches in in electrical boxes of different sizes (e.g., 1-gang, 2-gang, 3-gang, etc.). Rather, a frame and bezel for the particular size electrical box allows the same switch module, touch sensor, display, and control board assembly to be used in the different sized boxes. Additionally, the modular switches can include multiple relays permitting control over multiple loads with a single assembly (rather than requiring multiple complete, separate switch assemblies—one for each load). The example smart switches also control the number of virtual switches so that a virtual switch is not displayed for any unused relay.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “has,” “have,” “having,” “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The explicit description of the present invention has been presented for purposes of illustration and description, but is not intended to be exhaustive or limited to embodiments of the invention in the form explicitly disclosed. Many modifications and variations will be apparent to those of ordinary skill in the art without departing from the scope and spirit of embodiments of the invention. The embodiment was chosen and described in order to best explain the principles of embodiments of the invention and the practical application, and to enable others of ordinary skill in the art to understand embodiments of the invention for various embodiments with various modifications as are suited to the particular use contemplated.

Although specific embodiments have been illustrated and described herein, those of ordinary skill in the art appreciate that any arrangement which is calculated to achieve the same purpose may be substituted for the specific embodiments shown and that embodiments of the invention have other applications in other environments. This application is intended to cover any adaptations or variations of the present invention. The following claims are in no way intended to limit the scope of embodiments of the invention to the specific embodiments described herein.

What is claimed is:

1. A touch panel smart switch comprising:
a switch module comprising:
a first terminal for connection to a first load;
a second terminal for connection to a power source; and
a first relay connected to the first terminal and the second terminal for selectively connecting and disconnecting the first load to the power source; and
a removable faceplate module communicatively couple to the switch module, the faceplate module comprising:
a touch sensor configured to detect a touch input by a user;
a display device configured for displaying virtual switches at locations at which the touch sensor can detect a touch input by the user;
a processor communicatively coupled to the touch sensor, the display device, and the switch module; and
a memory device storing instruction that, when executed by the processor, cause the processor to:
display a first virtual switch at a first location on the display device; and
selectively connect the first load to the power source using the first relay in response to the touch sensor detecting a touch input by the user at the first location of the first virtual switch displayed on the display device.

2. The touch panel smart switch of claim 1, wherein the faceplate module further comprises a communications module communicatively coupled to the processor, the communications module configured for wireless communication with a remote device.

3. The touch panel smart switch of claim 2, wherein the faceplate module further comprises a microphone to detect voice input from a user, and the processor is further programmed to transmit the detected voice input to the remote device.

4. The touch panel smart switch of claim 1, wherein the faceplate module further comprises at least one sensor selected from a proximity sensor, a light sensor, a motion sensor, and a temperature sensor.

5. The touch panel smart switch of claim 1, wherein the switch module further comprises:
a third terminal for connection to a second load;
and
a second relay connected to the third terminal and the second terminal for selectively connecting and disconnecting the second load to the power source.

6. The touch panel smart switch of claim 5, wherein the memory further comprises instructions that cause the processor to:
receive a user selection of which of the first and second relays to use; and
display a virtual switch on the display device for each of the first and second relays selected by the user selection.

7. The touch panel smart switch of claim 5, wherein the memory further comprises instructions that cause the processor to:
display a second virtual switch at a second location on the display device; and
selectively connect the second load to the power source using the second relay in response to the touch sensor detecting a touch input by the user at the second location of the second virtual switch displayed on the display device.

8. The touch panel smart switch of claim 1, further comprising an insulating case configured for installation within an electrical box, wherein the switch module is attached to and disposed within the insulating case.

9. The touch panel smart switch of claim 8, wherein the insulating case has a width of less than 48 mm.

10. The touch panel smart switch of claim 8, wherein the insulating case has a width of less than 46 mm.

11. The touch panel smart switch of claim 8, wherein the insulating case includes a first side and a second side opposite the first side in a width direction, a first type interlocking connector is formed on the first side of the insulating case, and a second type interlocking connector configured for connection to interlocking connectors of the first type is formed on the second side of the insulating case.

12. A method of installing touch panel smart switches, the method comprising:
installing N switch modules in an N-gang electrical box, wherein N is an integer value greater than 0, each switch module including at least one relay for selectively connecting and disconnecting at least one load to a power source;
selecting a faceplate module for N switch modules from a plurality faceplate modules, each faceplate module of the plurality of faceplate modules being configured for use with a different number of switch modules, the selected removable faceplate module including:
N touch assemblies, each touch assembly including a touch sensor configured to detect a touch input by a user; and
N control board assemblies, each control board assembly including a display device, and a control board, the control board including a processor and a memory device storing instructions for execution by the processor; and
communicatively coupling each of the N control board assemblies to a different one of the N switch modules.

13. The method of claim 12, wherein each switch module of the N switch modules is installed within an insulating case, and installing the N switch modules comprises installing the N switch modules and their insulating cases in an N-gang electrical box.

14. The method of claim 13,
wherein each insulating case includes a first type interlocking connector formed on a first side of the insulating case, and a second type interlocking connector configured for connection to interlocking connectors of the first type formed on the second side of the insulating case; and
the method further comprises, when N is greater than 1, connecting the insulating cases of adjacent switch modules together using the first type interlocking connectors of one insulating case and the second type interlocking connectors of an adjacent insulating case.

15. The method of claim 13, further comprising mechanically attaching the removable faceplate module to the insulating cases of the N switch modules.

16. The method of claim 12, wherein selecting a faceplate module for N switch modules from a plurality faceplate modules comprises selecting a faceplate module for N switch modules from a plurality faceplate modules that includes a bezel and a frame having N openings, each opening of the frame houses one of the N touch assemblies and one of the N control assemblies.
